(19) United States
(12) Patent Application Publication
(10) Pub. No.: US 2025/0199252 A1
(43) Pub. Date: Jun. 19, 2025

(54) PACKAGE ASSEMBLY AND METHOD OF FORMING THE SAME

(71) Applicant: Taiwan Semiconductor Manufacturing Company, Ltd., Hsinchu (TW)

(72) Inventors: Chen-Hua Yu, Hsinchu City (TW); Tung-Liang Shao, Hsinchu (TW); Yu-Sheng Huang, Changhua County (TW)

(73) Assignee: Taiwan Semiconductor Manufacturing Company, Ltd., Hsinchu (TW)

(21) Appl. No.: 18/403,735

(22) Filed: Jan. 4, 2024

Related U.S. Application Data
(60) Provisional application No. 63/609,870, filed on Dec. 14, 2023.

(51) Int. Cl. G02B 6/42; H01L 23/00; H01L 23/498; H01L 23/522; H01L 25/16

(52) U.S. Cl. CPC G02B 6/4214; G02B 6/4239; H01L 25/167; H01L 23/49816; H01L 23/5226; H01L 24/05; H01L 24/16; H01L 24/32; H01L 24/73; H01L 2224/0401; H01L 2224/16227; H01L 2224/32225; H01L 2224/73204

(57) ABSTRACT

A method of forming a package assembly includes the following operations. A semiconductor package including an interposer structure and an overlying photonic structure is provided. An optical package is placed on the semiconductor package, wherein the optical package includes s a substrate, a lid and a fiber array unit interposed between the substrate and the lid. An optical glue is dispensed into a space between the semiconductor package and the optical package. A location of the optical package is adjusted after dispensing the optical glue. The optical glue is cured by irradiating a light through the optical package.

### CROSS-REFERENCE TO RELATED APPLICATION

This application claims the priority benefit of U.S. provisional application Ser. No. 63/609,870, filed on Dec. 14, 2023. The entirety of the above-mentioned patent application is hereby incorporated by reference herein and made a part of this specification.

### BACKGROUND

In recent years, the semiconductor industry has experienced rapid growth due to continuous improvement in integration density of various electronic components, e.g., transistors, diodes, resistors, capacitors, etc. For the most part, this improvement in integration density has come from successive reductions in minimum feature size, which allows more components to be integrated into a given area. Although the existing integrated circuit packages or package assemblies have been generally adequate for their intended purposes, they have not been entirely satisfactory in all respects.

### BRIEF DESCRIPTION OF THE DRAWINGS

FIG. 1 to FIG. 6 are schematic cross-sectional views of a method of forming a package assembly in accordance with some embodiments.

FIG. 7A, FIG. 7B, FIG. 7C, FIG. 7D, FIG. 7E, FIG. 7F, FIG. 7G, FIG. 7H, FIG. 7I, FIG. 7J, FIG. 8, FIG. 9, FIG. 10A, FIG. 10B, FIG. 11A and FIG. 11B illustrate varying views of a method of forming an optical package in accordance with some embodiments.

FIG. 12 to FIG. 17 are schematic cross-sectional views of a method of forming a package assembly in accordance with some embodiments.

FIG. 18A, FIG. 18B, FIG. 18C, FIG. 19A and FIG. 19B illustrate varying views of a method of forming an optical package in accordance with some embodiments.

FIG. 20 illustrates a method of forming a package assembly in accordance with some embodiments.

FIG. 21 illustrates a method of forming a package assembly in accordance with some embodiments.

### DETAILED DESCRIPTION

The following disclosure provides many different embodiments, or examples, for implementing different features of the provided subject matter. Specific examples of components and arrangements are described below for the purposes of conveying the disclosure in a simplified manner. These are, of course, merely examples and are not intended to be limiting. For example, the formation of a second feature over or on a first feature in the description that follows may include embodiments in which the second and first features are formed in direct contact, and may also include embodiments in which additional features may be formed between the second and first features, such that the second and first features may not be in direct contact. In addition, the same or similar reference numerals and/or letters may be used to refer to the same or similar element in the various examples of the disclosure. The repeated use of the reference numerals is for the purpose of simplicity and clarity and does not in itself dictate a relationship between the various embodiments and/or configurations discussed.

Further, spatially relative terms, such as “beneath”, “below”, “lower”, “on”, “over”, “overlying”, “above”, “upper” and the like, may be used herein to facilitate the description of one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments described herein disclose package assemblies such as photonic-electric integrated circuit (IC) packages. In the disclosure, the substrate with V-grooves for holding a fiber array unit (FAU) is transparent in at least a portion thereof. Therefore, after an ultra-violet (UV) curable optical glue is dispensed into the space between the substrate and the underlying photonic structure, a UV light can pass through the transparent portion of the substrate during the optical glue curing process, so as to increase the adhesion between the substrate and the underlying photonic structure and therefore improve the FAU integration. With optical interconnection provided by the photonic structure, higher communication performance and more compact packaging can be easily achieved.

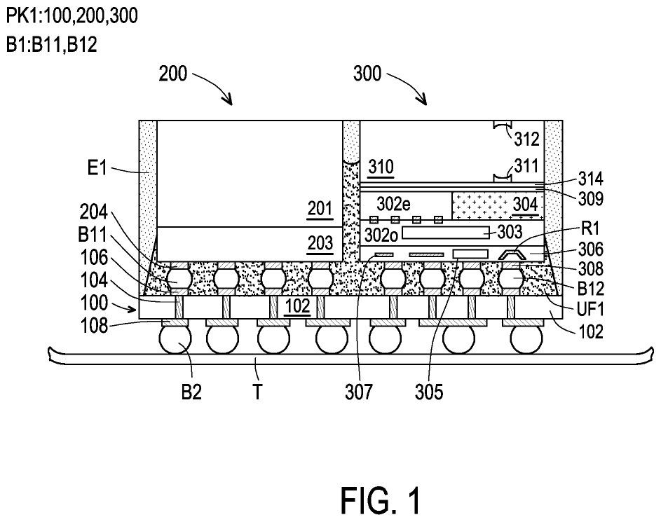

FIG. 1 to FIG. 6 are schematic cross-sectional views of a method of forming a package assembly in accordance with some embodiments. It is understood that the disclosure is not limited by the method described below. Additional operations can be provided before, during, and/or after the method and some of the operations described below can be replaced or eliminated, for additional embodiments of the methods. Although FIG. 1 to FIG. 6 are described in relation to a method, it is appreciated that the structures disclosed in FIG. 1 to FIG. 6 are not limited to such a method, but instead may stand alone as structures independent of the method.

Referring to FIG. 1, at least one semiconductor package PK1 is attached to a wafer tape T. In some embodiments, the semiconductor package PK1 includes an interposer structure 100, an integrated circuit structure 200 and an photonic structure 300 bonded to the interposer structure 100. The integrated circuit structure 200 may include a system device, and the photonic structure 300 may include a photonic device, which will be described in details below. However, the disclosure is not limited thereto. In other embodiments, the semiconductor package PK1 further includes an additional integrated circuit structure bonded to the interposer structure 100 and aside the integrated circuit structure 200. The additional integrated circuit structure may include a memory device such as a dynamic random-access memory (DRAM), a synchronous dynamic random-access memory (SDRAM), a die stack such as a high bandwidth memory (HBM) cube, or the like.

In some embodiments, the interposer structure 100 includes a substrate 102, and through substrate vias 104 penetrating through the substrate 102. The substrate 102 may include elementary semiconductor such as silicon, germanium and/or a compound semiconductor such as silicon germanium, silicon carbide, gallium arsenic, indium arsenide, gallium nitride or indium phosphide. The through substrate vias 104 may include metal such as copper and may be insulated from the substrate 102 by insulating liners. In some embodiments, the interposer structure 100 further includes a conductive structure disposed between the substrate 102 and the integrated circuit structure 200 or the photonic structure 300 and electrically connected to the through substrate vias 104. The conductive structure may include conductive features embedded by dielectric layers.

In some embodiments, the interposer structure 100 further includes metal pads 104 and metal pads 108 at opposite sides and configured to electrically connect to the overlying and underlying electrical components, semiconductor devices or integrated circuit structures, respectively. In some embodiments, bumps B1 and bumps B2 are further formed on and electrically connected to the metal pads 104 and the metal pads 108, respectively. The bumps B1 may be divided into bumps B11 and bumps B12 for different overlying electrical structures. The bumps B1 and the bumps B2 may include solder bumps, and/or may include metal pillars (e.g., copper pillars), solder caps formed on metal pillars, and/or the like. The bumps B1 are referred to as “micro bumps” in some examples. The bumps B2 are referred to as “controlled collapse chip connection (C4) bumps” in some examples. The size of the bumps B2 may be different from (e.g., greater than) the size of the bumps B1.

In some embodiments, the interposer structure 100 is an active interposer that contains at least one functional device or integrated circuit device included in the conductive structure or the substrate. Such active interposer is referred to as a “device-containing interposer” in some examples. In some embodiments, the functional device includes an active device, a passive device, or a combination thereof. The functional device includes, for example but not limited to, transistors, capacitors, resistors, diodes, photodiodes, fuse devices and/or other similar components. In other embodiments, the interposer structure 100 is a passive interposer, which is lack of a functional device or integrated circuit device. Such passive interposer is referred to as a “device-free interposer” in some examples.

Still referring to FIG. 1, an integrated circuit structure 200 is bonded to the interposer structure 100. The integrated circuit structure 200 may include a system device such as application-specific integrated circuit (ASIC), a field programmable gate array (FPGA), a central processing unit (CPU) die, a graphics processing unit (GPU) die, a multi-core general purpose processors (xPU) die, an artificial intelligence (AI) engine die, a transceiver (TRX) die, or the like. In some embodiments, the integrated circuit structure 200 (e.g., system device) includes a substrate 201 and a device layer 203. The substrate 201 may include elementary semiconductor such as silicon, germanium and/or a compound semiconductor such as silicon germanium, silicon carbide, gallium arsenic, indium arsenide, gallium nitride or indium phosphide. The substrate 201 may be doped as needed. The device layer 203 may include a transistor such as a fin field effect transistor (FinFET), a nanostructure FET (nano-FET) (e.g., a nanosheet transistor, a nanowire transistor or a gate-all-around transistor), a planar FET, the like, or a combination thereof. The device layer 203 may further include an interconnect structure electrically connected to the transistor.

In some embodiments, the integrated circuit structure 200 (e.g., system device) further includes metal pads 204 configured to electrically connect to the underlying electrical component, semiconductor device or integrated circuit structure. Specifically, the integrated circuit structure 200 (e.g., system device) is bonded to the interposer structure 100 through the metal pads 204, bumps B11 and the metal pads 104. The bumps B11 may be formed over the metal pads 204, the metal pads 104 or both.

Still referring to FIG. 1, a photonic structure 300 is bonded to the interposer structure 100. In some embodiments, the photonic structure 300 includes, from bottom to top, a photonic die 302o, an electric die 302e and a support die 310. The photonic structure 300 may be referred to as a silicon photonic (SiPh) structure in some examples.

In some embodiments, the photonic die 302o includes a photonic integrated circuit (PIC) 303. The PIC 303 includes an optical waveguide (such as silicon (Si) waveguide), a modulator, a detector, a grating coupler, a filter, other optical components, or a combination thereof. In some embodiments, the photonic die 302o further includes at least one reflector R1, at least one optical component 305, and conducive features 307 embedded in at least one dielectric layer 306. The reflector R1 is configured to reflect a light beam to the desired direction or the desired optical component. The optical component 305 is optically coupled to the PIC 303. In some embodiments, the optical component 305 includes an edge coupler (EC) and an optical waveguide, and the edge coupler is between the reflector R1 and the optical waveguide. The optical waveguide included in the optical component 305 includes a silicon nitride (SiN) waveguide, a silicon carbide (SiC) waveguide, a silicon carbon nitride (SiCN) waveguide or the like. The material of the optical waveguide in the dielectric layer 306 is different from the material of the optical waveguide inside the PIC 303. The silicon nitride waveguide in the optical component 305 has a lower signal propagation loss than the silicon waveguide in the PIC 303, and is used to transmit the optical signal over a relatively longer distance. The conducive features 307 of the photonic structure 300 are configured to electrically connect to the underlying interposer structure 100. The reflector R1 and the conducive features 307 may include metal (such as copper) and may be formed by electroplating processes or sputtering processes. The dielectric layer 306 may include silicon oxide, silicon nitride, silicon oxynitride, the like, or a combination thereof, and may be formed by deposition processes.

In some embodiments, the method of forming the photonic die 302o may include: providing a silicon-on-insulator (SOI) substrate, forming a PIC 303 on/in the active side (e.g., front side) of a silicon layer of the SOI substrate, removing an oxide layer and a semiconductor layer of the SOI substrate, and forming at least one optical component 305, at least one reflector R1 and conducive features 307 embedded in at least one dielectric layer 306 on the non-active side (e.g., backside) of the silicon layer.

In some embodiments, the electric die 302e includes an electric integrated circuit (EIC). The PIC of the photonic die 302o is integrated with the EIC of the electric die 302e, so as to achieve a higher communication performance and a more compact packaging. In some embodiments, the electric die 302e is bonded to the photonic die 302o through a hybrid bonding including a dielectric-to-dielectric bonding and a metal-to-metal bonding.

In some embodiments, the dimension (e.g., width) of the electric die 302e is less than the dimension (e.g., width) of the photonic die 302o, and an insulating material 304 is provided aside the electric die 302e to fill the space and robust the structure. The insulating material 304 may include a dielectric material, a polymer material or a combination thereof. The dielectric material may include silicon oxide, silicon nitride, silicon oxynitride, the like, or a combination thereof, and may be formed by a deposition process. The polymer material may include polybenzoxazole (PBO), polyimide (PI), benzocyclobutene (BCB), a molding compound (e.g., epoxy) and may be formed by a depositing process or a molding process.

In some embodiments, the support die 310 is a semiconductor die, such as a silicon die. The support die 310 may include elementary semiconductor such as silicon, germanium and/or a compound semiconductor such as silicon germanium, silicon carbide, gallium arsenic, indium arsenide, gallium nitride or indium phosphide.

In some embodiments, the support die 310 includes at least one optical lens 311 and at least one optical lens 312 at opposite sides thereof. The optical lens 311 and the optical lens 312 may be aligned with each other. The optical lens 311 and the optical lens 312 may be embedded in the support die 310 and face each other. The optical lens 311 and the optical lens 312 are configured to condense a light beam in a desired cross section, or focus a light beam in the desired direction. In some embodiments, each of the optical lens 311 and the optical lens 312 may have an optical recessed feature. In some embodiments, each of the optical lens 311 and the optical lens 312 has a substantially vertical sidewall and a convex bottom. The shape of the optical lens 311 may be symmetrical to the shape of the optical lens 312, and may be designed to have the desired curvature for focusing a light beam to the underlying optical component.

In some embodiments, the method of forming each of the optical lens 311 and the optical lens 312 includes performing an etching process or a laser process to formed a recessed feature, and filling the recessed feature with an optical material or a transparent material. The optical material has a transmission percentage of about 80-99% (e.g., 85-95% or 88-92%). In some embodiments, the optical material includes an optical liquid silicone rubber, poly(methyl methacrylate) (PMMA), an optical epoxy, the like, or a combination thereof. In some embodiments, the optical material includes a high numerical aperture (NA) material having a NA of about 0.2 to 0.5. In some embodiments, the optical material is formed using dispensing, injecting, and/or spraying process, followed by a planarization process.

In some embodiments, the support die 310 is bonded to the electric die 302e through a fusion bonding such as a dielectric-to-dielectric bonding or a polymer-to-polymer bonding. Specifically, the support die 310 is bonded to the electric die 302e through a dielectric bonding layer 314 and a dielectric bonding layer 309. Each of the dielectric bonding layer 314 and the dielectric bonding layer 309 includes a dielectric layer such as silicon oxide, silicon nitride, silicon oxynitride, silicon oxycarbide, the like, or a combination thereof. The dielectric layer may be replaced by a polymer layer or an insulating layer as needed.

In some embodiments, the photonic structure 300 (e.g., photonic device) further includes metal pads 308 configured to electrically connect to the underlying electrical component, semiconductor device or integrated circuit structure. Specifically, the photonic structure 300 (e.g., photonic device) is bonded to the interposer structure 100 through the metal pads 308, bumps B12 and the metal pads 104. The bumps B12 may be formed over the metal pads 308, the metal pads 104 or both.

Still referring to FIG. 1, after the integrated circuit structure 200 and the photonic structure 300 are bonded to the interposer structure 100, an underfill layer UF1 is formed to fill the space between the interposer structure 100 and each of the integrated circuit structure 200 and the photonic structure 300, and surrounds the bumps B1 including bumps B11 and B12. In some embodiments, the underfill layer UF1 includes a molding compound such as epoxy, and is formed using dispensing, injecting, and/or spraying process. The underfill layer UF1 between two adjacent structures may have a curve and concave surface. The underfill layer UF1 may be omitted in some examples.

Thereafter, an encapsulation layer E1 is formed over the interposer structure 100 and laterally surrounds the integrated circuit structure 200 and the photonic structure 300. In some embodiments, the encapsulation layer E1 includes a molding compound, a molding underfill, a resin or the like. In some embodiments, the encapsulation layer E1 includes a polymer material such as polybenzoxazole (PBO), polyimide, benzocyclobutene (BCB), the like, or a combination thereof. The encapsulation layer E1 may be formed by a molding process followed by a curing process.

In some embodiments, a wafer dicing process is performed, so as to separate adjacent semiconductor packages PK1 from each other. Each semiconductor package PK1 may have substantially straight sidewalls. In some embodiments, the semiconductor package PK1 includes an interposer structure 100, an integrated circuit structure 200 and an photonic structure 300 bonded to the interposer structure 100, and an encapsulation layer E1 laterally encapsulates sidewalls of the integrated circuit structure 200 and the photonic structure 300.

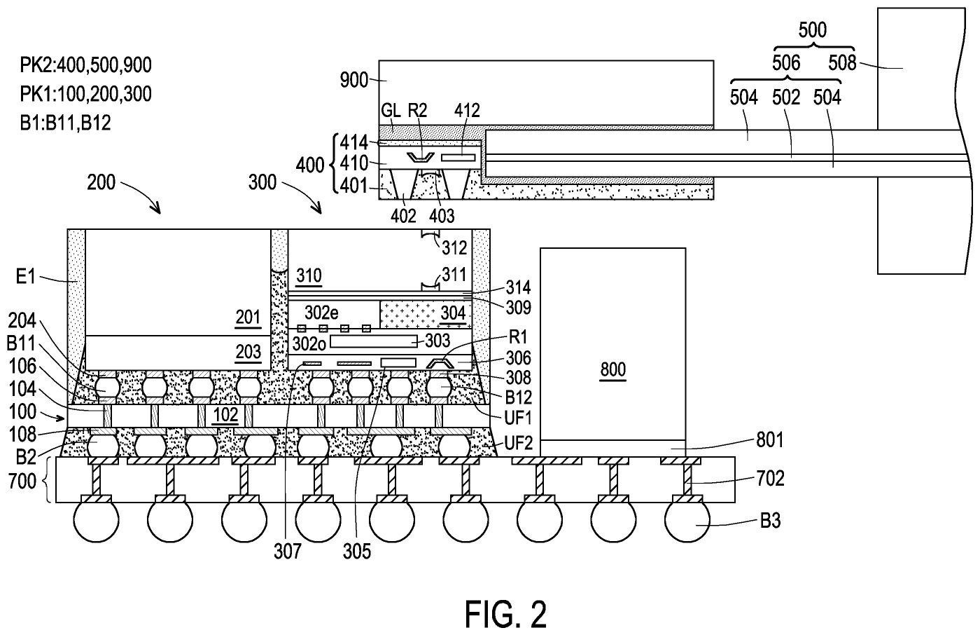

Referring to FIG. 1 and FIG. 2, the wafer tape T is removed, and a board substrate 700 is formed below and electrically connected to the interposer structure 100. In some embodiments, the board substrate 700 is bonded to the interposer structure 100 through the bumps B2.

In some embodiments, the board substrate 700 includes a core layer and two build-up layers on opposite sides of the core layer. In some embodiments, the board substrate 700 includes wiring patterns 702 that penetrate through the core layer and the build-up layers for providing electrical routing between different devices and electric components. The wiring patterns 702 include lines, vias, pads and/or connectors. The board substrate 700 is referred to as a “printed circuit board (PCB)” in some examples. In other embodiments, the core layer of the board substrate 700 may be omitted as needed, and such board substrate 700 is referred to as a “coreless board substrate”.

Thereafter, an underfill layer UF2 is formed to fill the space between the interposer structure 100 and the board substrate 700, and surrounds the bumps B2. In some embodiments, the underfill layer UF2 includes a molding compound such as epoxy, and is formed using dispensing, injecting, and/or spraying process.

In some embodiments, a support structure 800 is provided and bonded to the board substrate 700 aside the photonic structure 300 of the semiconductor package PK1. The support structure 800 is configured to support the overlying optical package PK2 (as shown in FIG. 2) and therefore robust the final structure. In some embodiments, the support structure 800 is a wall structure at a single side of the photonic structure 300, or a ring structure surrounding the photonic structure 300. In such case, the support structure 800 include a heat dissipation material, such as metal. The support structure 800 is attached to the board substrate 700 through an adhesive layer 801. However, the disclosure is not limited thereto. In other embodiments, the support structure 800 may be a silicon dummy die for eliminating the coefficient thermal expansion (CTE) mismatch and therefore reducing the package warpage issue.

Afterwards, bumps B3 are formed below and electrically connected to the board substrate 700. In some embodiments, bump B3 are electrically to the wiring patterns 702 of the board substrate 700. In some embodiments, the bumps B3 may include solder bumps, and/or may include metal pillars (e.g., copper pillars), solder caps formed on metal pillars, and/or the like. The bumps B3 are referred to as “ball grid array (BGA) balls” in some examples. The size of the bumps B3 may be different from (e.g., greater than) the size of the bumps B2.

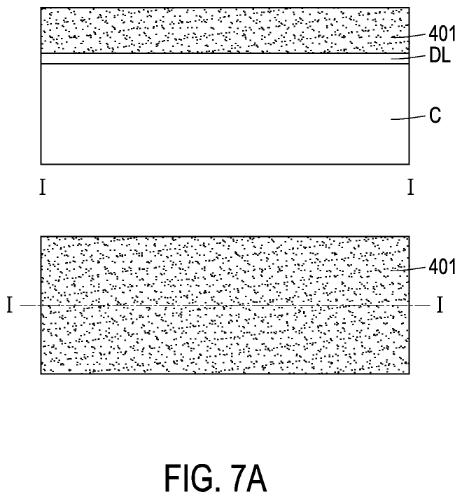

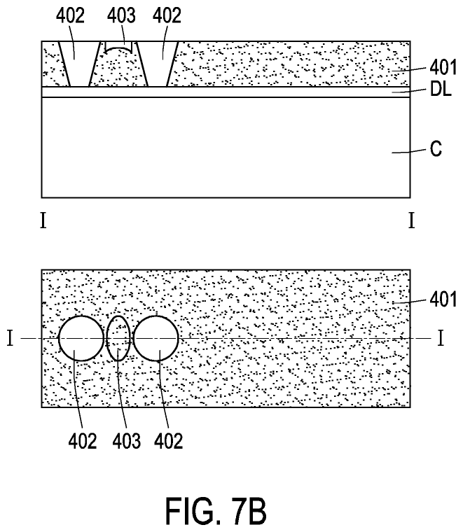

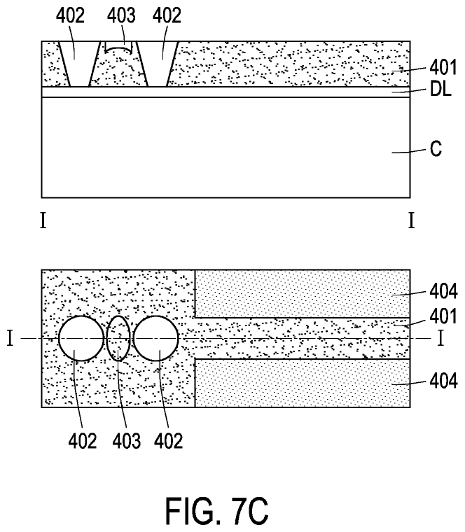

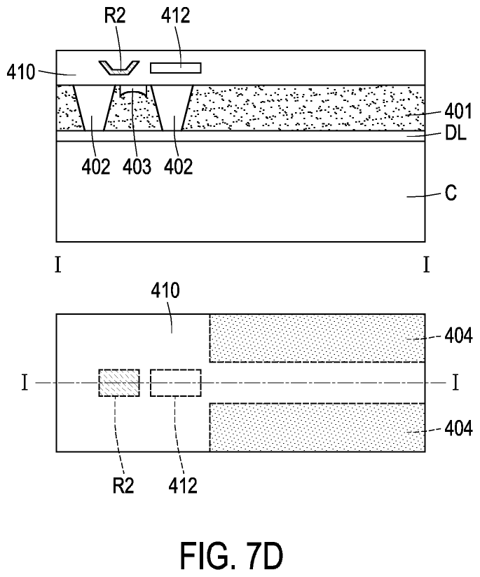

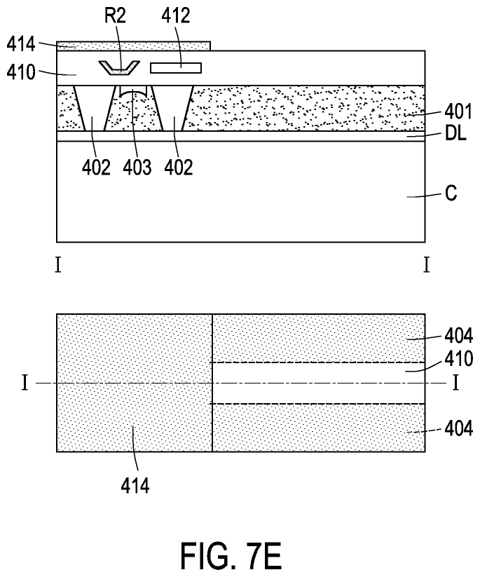

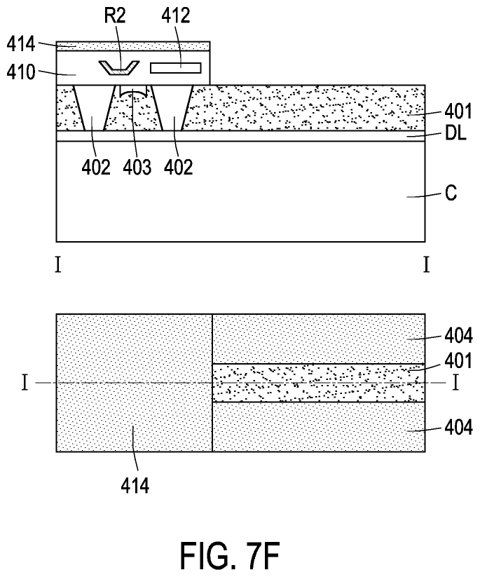

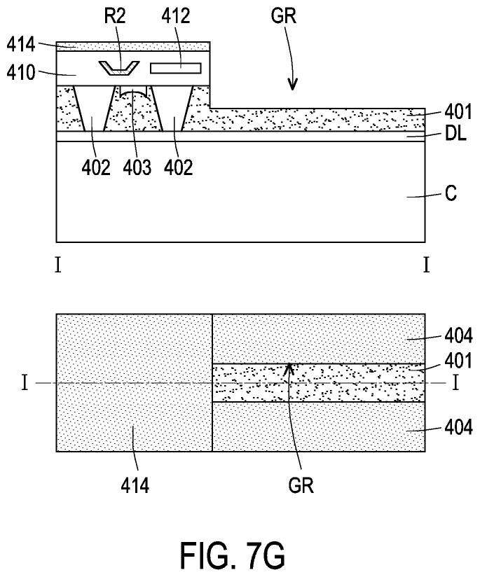

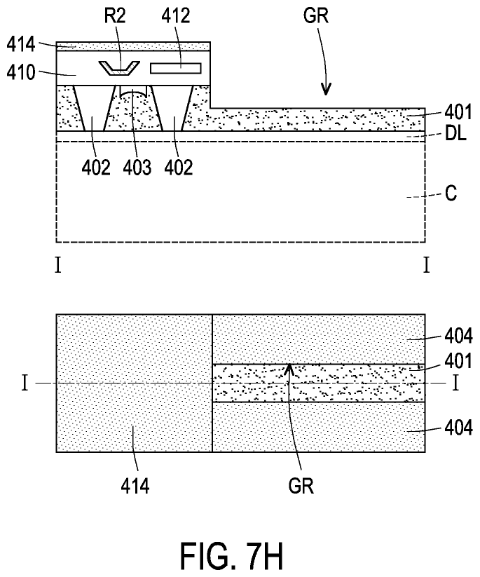

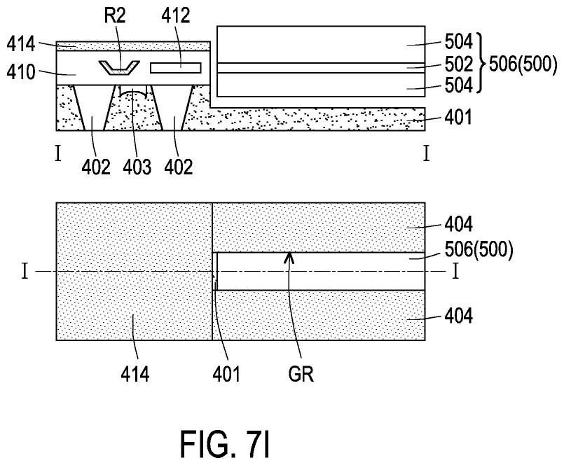

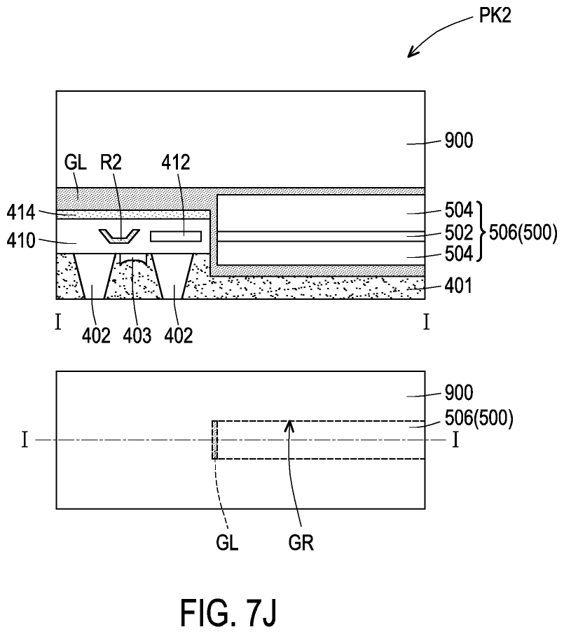

Referring to FIG. 2, an optical package PK2 is provided over the semiconductor package PK1. In some embodiments, the optical package PK2 includes a fiber array unit (FAU) 500 embedded in a substrate 400 (or called a “carrier” in some examples) and covered by a lid 900 (or called a “cover” in some examples). In some embodiments, the substrate 400 includes a base substrate 401, a dielectric layer 410, a hard mask layer 414 and all the optical components formed in the above layers. The method of forming the optical package PK2 is described in varying views in FIG. 7A to FIG. 7J, FIG. 8, FIG. 9, FIG. 10A, FIG. 10B, FIG. 11A and FIG. 11B. In each of FIG. 7A to FIG. 7, a simplified top view and the corresponding cross-sectional view taken along the line I-I are shown. FIG. 8 and FIG. 9 illustrate simplified top views of some components. FIG. 10A illustrates a simplified top view of some components, and FIG. 10B illustrates a cross-sectional view taken along the line II-II of FIG. 10A. FIG. 11A illustrates a simplified top view of some components, and FIG. 11B illustrates a cross-sectional view taken along the line II-II of FIG. 11A.

Referring to FIG. 7A, a base substrate 401 is formed on a carrier C, and a de-bonding layer DL formed between the carrier C and the base substrate 401. The carrier C may be a glass carrier or any suitable carrier for carrying a substrate. The de-bonding layer DL may include a release layer (e.g., a light-to-heat conversion (LTHC) layer) or an adhesive layer (e.g., an ultra-violet curable adhesive or a heat curable adhesive layer). In some embodiments, the base substrate 401 is a semiconductor substrate including elementary semiconductor such as silicon, germanium and/or a compound semiconductor such as silicon germanium, silicon carbide, gallium arsenic, indium arsenide, gallium nitride or indium phosphide. The base substrate 401 may include a light-blocking material or an opaque material. The base substrate 401 may be referred to as a “semiconductor carrier”, a “light-blocking substrate” or an “opaque substrate” in some examples.

Referring to FIG. 7B, one or more light-transmitting regions 402 are formed in the base substrate 401. In some embodiments, the method of forming the light-transmitting regions 402 includes forming holes penetrating through the base substrate 401 by photolithography and etching processes, filling a light-transmitting material in the holes by a deposition process, and removing the excess light-transmitting material outside of the holes by a planarization process or a grinding process. The light-transmitting regions 402 may have inclined sidewalls, as shown in FIG. 7B. However, the disclosure is not limited thereto. In other embodiments, the light-transmitting regions 402 may have substantially straight sidewalls. In some embodiments, the light-transmitting material includes silicon oxide, silicon nitride, silicon oxynitride, silicon carbide, or a transparent material. For example, the light-transmitting material includes silicon oxide. The light-transmitting regions 402 may be referred to as “transparent regions” in some examples.

In some embodiments, at least one optical lens 403 is formed between the light-transmitting regions 402. In some embodiments, the optical lens 403 has a substantially vertical sidewall and a convex bottom. The optical lens 403 may be designed to have the desired curvature for focusing a light beam to the underlying optical component. In some embodiments, the method of forming the optical lens 403 includes performing an etching process or a laser process to formed a recessed feature, and filling the recessed feature with an optical material or a transparent material. The optical material has a transmission percentage of about 80-99% (e.g., 85-95% or 88-92%). In some embodiments, the optical material includes an optical liquid silicone rubber, poly(methyl methacrylate) (PMMA), an optical epoxy, the like, or a combination thereof. In some embodiments, the optical material includes a high numerical aperture (NA) material having a NA of about 0.2 to 0.5. In some embodiments, the optical material is formed using dispensing, injecting, and/or spraying process, followed by a planarization process. The optical lens 403 may be optional and may be omitted as needed. In some embodiments, the optical lens 403 may be formed before or after the formation of the light-transmitting regions 402. From a top view, the shape of the optical lens 403 is different the shape of the light-transmitting regions 402. The optical lens 403 may be oval or elliptical, and the light-transmitting regions 402 may be circular.

Referring to FIG. 7C, a first hard mask layer 404 is formed on the base substrate 401. The first hard mask layer 404 is configured to define the subsequently formed grooves for holding optical fibers 506 of the fiber array unit (FAU) 500 (as shown in FIG. 10A, FIG. 10B, FIG. 11A and FIG. 11B). Specifically, the first hard mask layer 404 exposes a region of the base substrate 401 which will be etched to define the grooves and exposes another region of the base substrate 401 having optical components formed therein. In some embodiments, the method of forming the first hard mask layer 404 includes depositing a first hard mask material followed by a patterning process (e.g., lithography and etching processes). The first hard mask material includes silicon oxide, silicon nitride, silicon oxynitride, silicon carbide, or the like. For example, the first hard mask material includes silicon nitride.

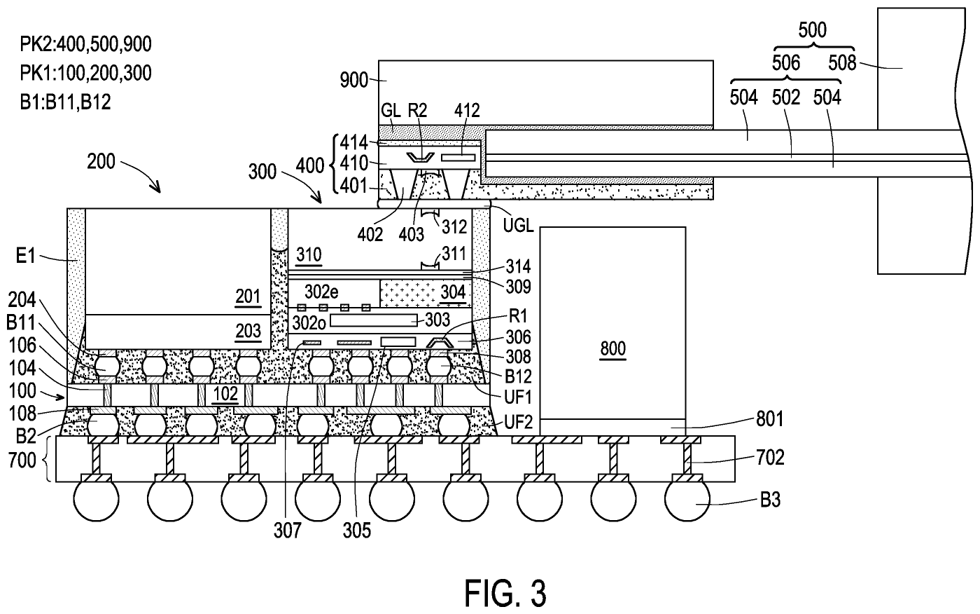

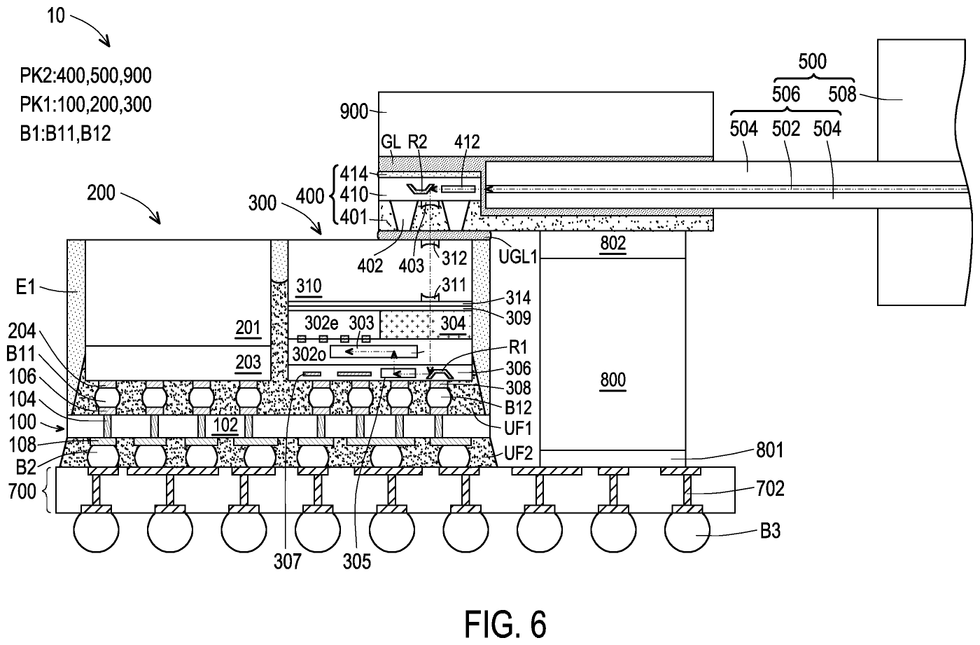

Referring to FIG. 7D, at least one reflector R2 and at least one optical component 412 embedded in at least one dielectric layer 410 are formed over the base substrate 401. The dielectric layer 410 may include silicon oxide, silicon nitride, silicon oxynitride, the like, or a combination thereof, and may be formed by deposition processes. The dielectric layer 410 covers the underlying first hard mask layer 404. The reflector R2 and the optical component 412 are configured to reflect and guide a light beam from an optical fiber to the desired optical component (e.g., the underlying optical lens 403, as shown in FIG. 3 to FIG. 6). The reflector R2 may include metal (such as copper) and may be formed by an electroplating process or a sputtering process. The optical component 412 is optically coupled to the PIC 303 of the photonic structure 300 and the FAU 500 (as shown in FIG. 6). Specifically, as shown in FIG. 8, FIG. 9, FIG. 10A, FIG. 10B, FIG. 11A and FIG. 11B, multiple reflectors R2 correspond to multiple optical components 412 (including multiple optical waveguides WG and multiple edge couplers EC) and therefore correspond to multiple grooves GR and the overlying optical fibers 506, respectively. In some embodiments, as shown in FIG. 8 and FIG. 9, each optical component 412 includes an edge coupler EC and an optical waveguide WG, and the edge coupler EC is between the reflector R2 and the optical waveguide WG. In some embodiments, multiple optical waveguides WG are configured to “direct” light beams (from multiple optical fibers) “straightly” toward the reflectors R2, respectively, as shown in FIG. 8 and FIG. 10A. However, the disclosure is not limited thereto. In other embodiments, multiple optical waveguides WG are configured to “direct” light beams (from multiple optical fibers) “narrowly” toward the reflectors R2, respectively, so those optical waveguides WG are called “fan-in waveguides”, as shown in FIG. 9 and FIG. 11A. In some embodiments, the optical waveguide WG included in each optical component 412 includes a silicon nitride (SiN) waveguide, a silicon carbide (SiC) waveguide, a silicon carbon nitride (SiCN) waveguide or the like. The material of the optical waveguide WG in the dielectric layer 410 is different from the material of the optical waveguide inside the PIC 303. The silicon nitride waveguide WG in the optical component 412 has a lower signal propagation loss than the silicon waveguide in the PIC 303, and is used to transmit the optical signal over a relatively longer distance.

Referring to FIG. 7E, a second hard mask layer 414 is formed on the dielectric layer 410. The second hard mask layer 414 is configured to define the subsequently formed grooves (as shown in FIG. 8, FIG. 9, FIG. 10A, FIG. 10B, FIG. 11A and FIG. 11B) with the first hard mask layer 404. In some embodiments, the second hard mask layer 414 covers a portion of the dielectric layer 410 having optical components formed therein while exposes another portion of the dielectric layer 410 free of optical components. In some embodiments, the method of forming the second hard mask material includes depositing a second hard mask material followed by a patterning process (e.g., lithography and etching processes). The second hard mask material includes silicon oxide, silicon nitride, silicon oxynitride, silicon carbide, or the like. For example, the second hard mask material includes silicon nitride. The second hard mask material may be the same as or different from the first hard mask material. The material included in the dielectric layer 410 and the material included in each of the second hard mask material and the first hard mask material have different etching selectivities.

Referring to FIG. 7F, the exposed portion of the dielectric layer 410 is removed by using the second hard mask layer 414 as a mask. The removing process includes an etching process such as a dry etching process. Upon the removing process, the underlying first hard mask layer 404 and the region of the base substrate 401 for defining the grooves are exposed.

Referring to FIG. 7G, the exposed portion of the base substrate 401 is removed by using the first mask layer 404 and the second mask layer 414 as a mask, so as to form one or more grooves GR in the base substrate 401. The removing process includes an etching process such as a wet etching process. In some embodiments, the etchant solution etches silicon of the base substrate 401 along a specific crystalline plan, so the grooves GR are formed as V-grooves, as shown in FIG. 10B and FIG. 11B. Specifically, the grooves GR have sharp V-shape bottoms. In some embodiments, the included angle θ between the top surface and the sidewall of each groove GR is about 50 to 70 degrees, such as about 55 to 65 degrees. The included angle θ is usually a fixed angle due to crystalline property.

Referring to FIG. 7H, the carrier C is de-bonded and removed from the base substrate 401. In some embodiments, the de-bonding layer DL is decomposed under heat of light, and the carrier C is then released from the backside of the base substrate 401.

Referring to FIG. 7I, FIG. 10A, FIG. 10B, FIG. 11A and FIG. 11B, multiple optical fibers 506 of the FAU 500 are placed on the grooves GR, respectively. Due to the fixed angle of the V-grooves GR, the optical fibers 506 sit on the groove precisely and stably. The optical fibers 506 arranged in an array. For example, the optical fibers 506 can be arranged in one row, two rows or more rows as needed. In some embodiments, each optical fiber 506 includes a glass core 502 and a glass cladding 504 surrounding the glass core 502. In some embodiments, as shown in FIG. 2, a portion of each optical fiber 506 is embedded in a ferrule 508, and the remaining portion of the optical fiber 506 is embedded in a fiber ribbon.

Referring to FIG. 7J, FIG. 10A, FIG. 10B, FIG. 11A and FIG. 11B, a lid 900 is provided over the base substrate 401, so the optical fibers 506 of the FAU 500 are interposed between the base substrate 401 and the lid 900. The lid 900 is configured to protect and fix the underlying base substrate 401 and the FAU 500. The lid 900 may be a glass lid or a transparent lid. Thereafter, an optical glue GL is dispensed into the space between the FAU 500 and each of the base substrate 401 and the lid 900 followed by a curing process. The optical glue GL includes a curable adhesive material and has high light transmittance and high adhesion. The optical glue GL may have a convex surface and extend out from the sidewall of the lid 900. The optical package PK2 including a fiber array unit (FAU) 500 interposed between a base substrate 401 and a lid 900 is thus completed.

Referring to FIG. 3, the optical package PK2 is placed on the semiconductor package PK1. In some embodiments, the optical lens 403 of the optical package PK2 corresponds to (e.g., vertically aligned to) the optical lens 312 of the underlying photonic structure 300 of the semiconductor package PK1.

Thereafter, a UV-curable optical glue UGL is dispensed into the space between the optical package PK2 and the semiconductor package PK1. The UV-curable optical glue UGL includes a UV-curable adhesive material and has high light transmittance and high adhesion. The UV-curable optical glue UGL may have a convex surface, may extend out from the sidewall of the base substrate 401 of the optical package PK2, and may extend out from the sidewall of the encapsulation layer E1 of the semiconductor package PK1. The “uncured” UV-curable optical glue UGL at this stage is softer and less adhesive, so the overlying optical package PK2 is movable and rotational in the horizontal direction (e.g., along X direction and/or Y direction) and in vertical direction (e.g., X direction). In some embodiments, the location of the optical package PK2 can be adjusted to an appropriate location before the UV-curable optical glue UGL is subjected to a UV curing process, so as to ensure that the optical package PK2 is in place and aligned with the semiconductor package PK1.

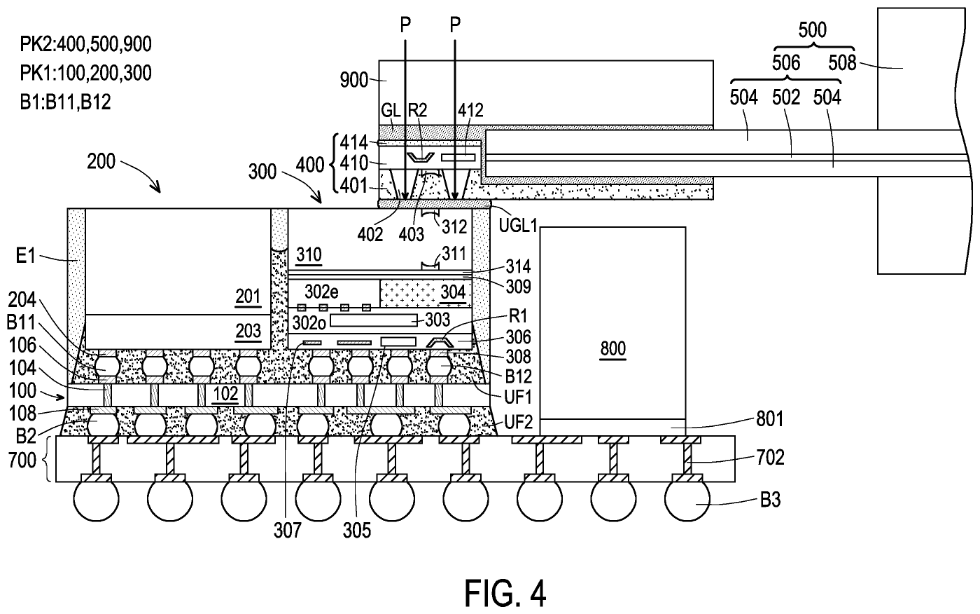

Referring to FIG. 4, a UV curing process P is performed, so a UV light passes through the light-transmitting regions 402 of the optical package PK2 and reaches the UV-curable optical glue, and the uncured UV-curable optical glue is cured and hardened to form a cured optical glue UGL1. Specifically, after the optical package PK2 is adjusted to the appropriate location, the UV-curable optical glue UGL is cured to fix the location of the optical package PK2.

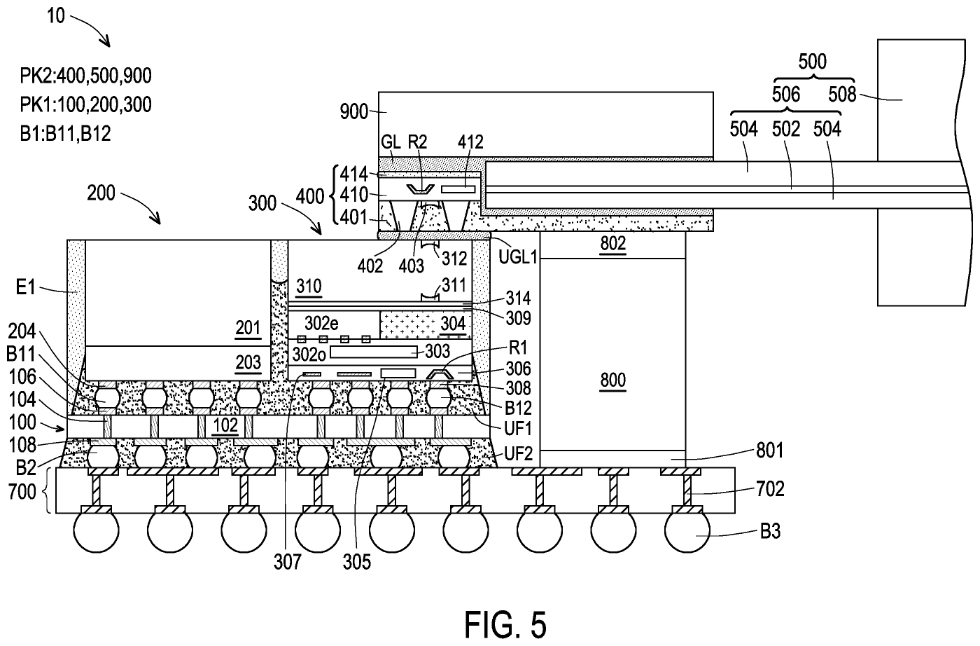

Referring to FIG. 5, after the UV curing process P, a buffer layer 802 is provided between the optical package PK2 and the support structure 800, so as to better support the optical package PK2 and therefore stabilize the entire package assembly. The buffer layer 802 may be an adhesive layer or a thermal interface material (TIM). The back surface of the base substrate 401 is in physical contact with the buffer layer 802 over the support structure 800. The buffer layer 802 is regarded as part of support structure 800 in some examples. A package assembly 10 of the disclosure is thus completed.

In some embodiments, as shown in FIG. 6, a light beam L propagates through an optical fiber 506, travels through an edge coupler and a silicon nitride waveguide of an optical component 412, is redirected by the reflector R2 and then optically coupled to a PIC 303 sequentially through an optical lens 312, an optical lens 311, a reflector R1, and an edge coupler and a silicon nitride waveguide of an optical component 305.

In the disclosure, the substrate with V-grooves for holding a fiber array unit (FAU) is provided with transparent regions. Therefore, after an ultra-violet (UV) curable optical glue is dispensed into the space between the substrate and the underlying photonic structure, a UV light can pass through the transparent regions of the substrate during the optical glue curing process, so as to increase the adhesion between the substrate and the underlying photonic structure and therefore improve the FAU integration.

In the above embodiments, a semiconductor substrate is formed with transparent regions, so a UV light can pass through the transparent regions and therefore cure the optical glue. However, the disclosure is not limited thereto. In other embodiments, a transparent substrate such as a glass substrate can be used instead of a semiconductor substrate, so a UV light can pass through the transparent substrate directly and therefore cure the optical glue.

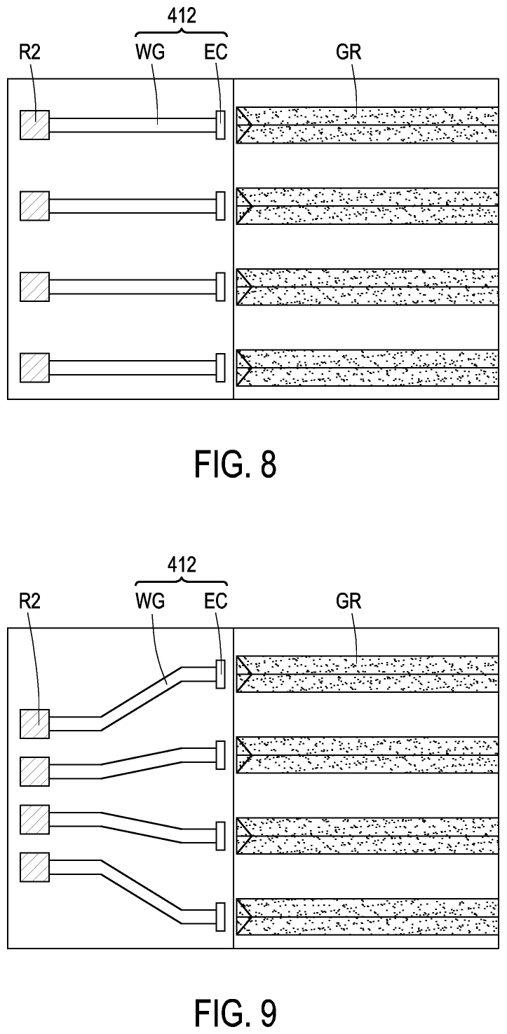

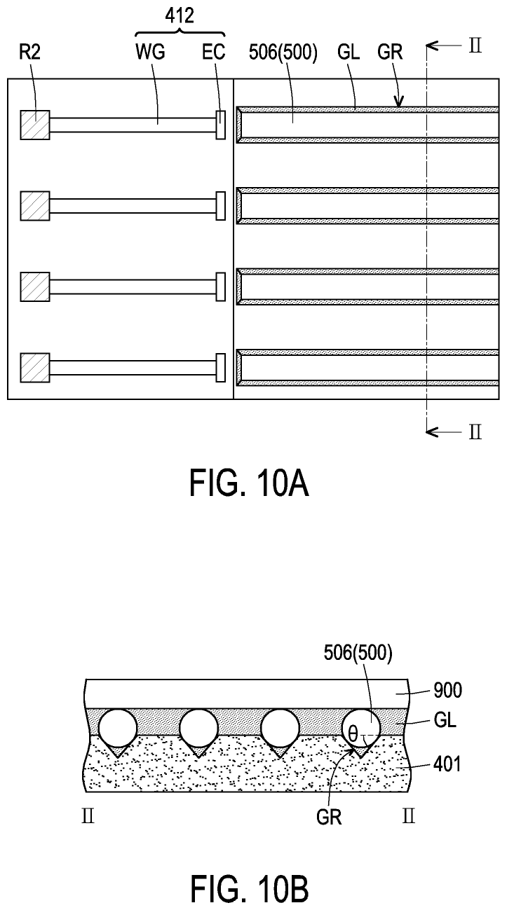

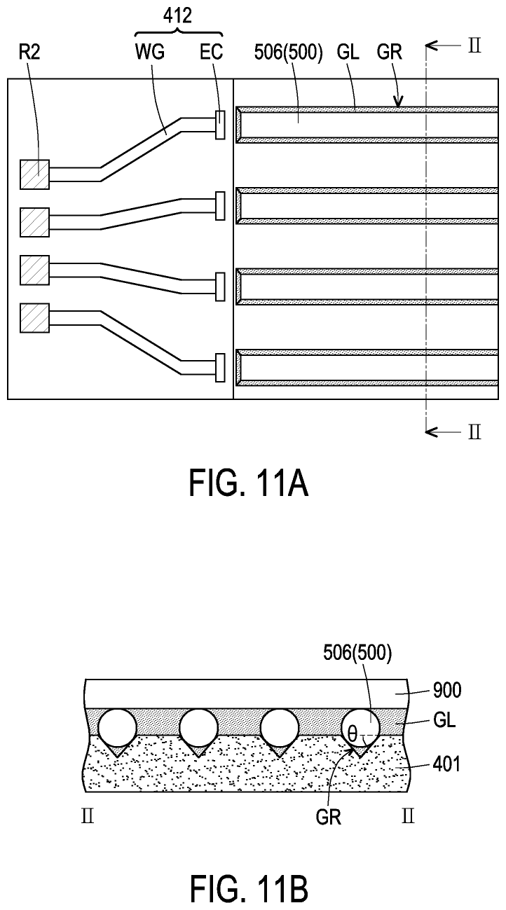

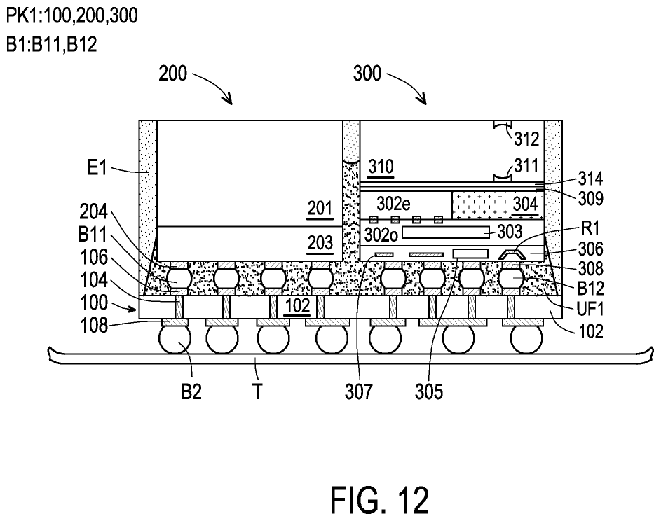

FIG. 12 to FIG. 17 are schematic cross-sectional views of a method of forming a package assembly in accordance with some embodiments. It is understood that the disclosure is not limited by the method described below. Additional operations can be provided before, during, and/or after the method and some of the operations described below can be replaced or eliminated, for additional embodiments of the methods. Although FIG. 12 to FIG. 17 are described in relation to a method, it is appreciated that the structures disclosed in FIG. 12 to FIG. 17 are not limited to such a method, but instead may stand alone as structures independent of the method.

The forming method of FIG. 12 to FIG. 17 is similar to the forming method of FIG. 1 to FIG. 6, and the difference between them lies in the substrate material of the optical package. Through the specification, the same or similar reference numerals and/or letters may be used to refer to the same or similar elements in the various examples of the disclosure, so the materials, configurations and/or forming methods of elements in FIG. 12 to FIG. 17 may refer to those described in above embodiments.

Referring to FIG. 12, at least one semiconductor package PK1 is attached to a wafer tape T. The semiconductor package PK1 has been described in FIG. 1, so the details are not iterated herein.

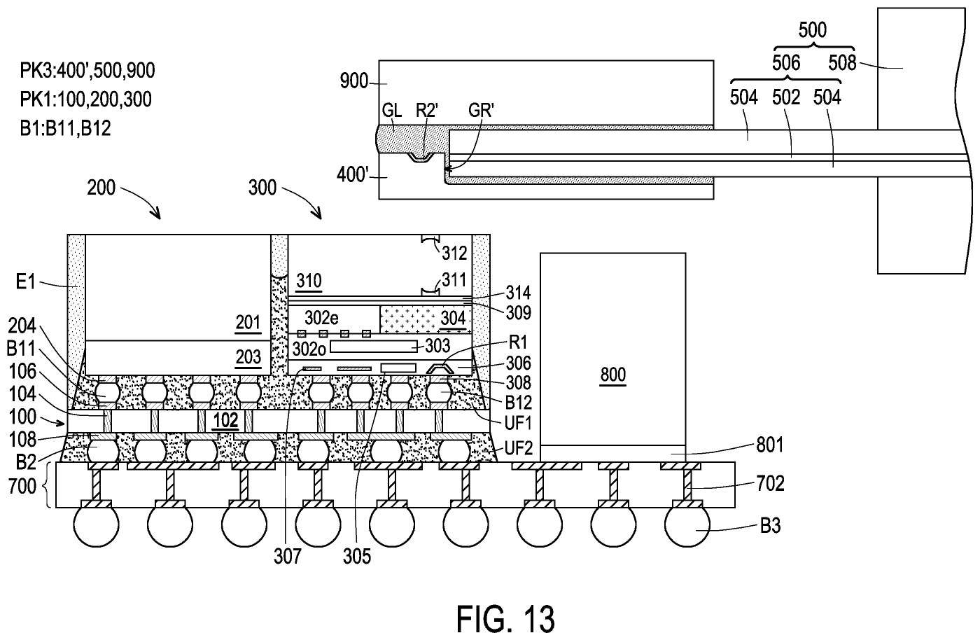

Referring to FIG. 13, the wafer tape T is removed, and a board substrate 700 is formed below and electrically connected to the interposer structure 100. In some embodiments, the board substrate 700 is bonded to the interposer structure 100 through the bumps B2.

In some embodiments, the board substrate 700 includes a core layer and two build-up layers on opposite sides of the core layer. In some embodiments, the board substrate 700 includes wiring patterns 702 that penetrate through the core layer and the build-up layers for providing electrical routing between different devices and electric components. The wiring patterns 702 include lines, vias, pads and/or connectors. The board substrate 700 is referred to as a “printed circuit board (PCB)” in some examples. In other embodiments, the core layer of the board substrate 700 may be omitted as needed, and such board substrate 700 is referred to as a “coreless board substrate”.

Thereafter, an underfill layer UF2 is formed to fill the space between the interposer structure 100 and the board substrate 700, and surrounds the bumps B2. In some embodiments, the underfill layer UF2 includes a molding compound such as epoxy, and is formed using dispensing, injecting, and/or spraying process.

In some embodiments, a support structure 800 is provided and bonded to the board substrate 700 aside the photonic structure 300 of the semiconductor package PK1. The support structure 800 is configured to support the overlying optical package PK3 (as shown in FIG. 13) and therefore robust the final structure. In some embodiments, the support structure 800 is a wall structure at a single side of the photonic structure 300, or a ring structure surrounding the photonic structure 300. In such case, the support structure 800 include a heat dissipation material, such as metal. The support structure 800 is attached to the board substrate 700 through an adhesive layer 801. However, the disclosure is not limited thereto. In other embodiments, the support structure 800 may be a silicon dummy die for eliminating the coefficient thermal expansion (CTE) mismatch and therefore reducing the package warpage issue.

Afterwards, bumps B3 are formed below and electrically connected to the board substrate 700. In some embodiments, bump B3 are electrically to the wiring patterns 702 of the board substrate 700. In some embodiments, the bumps B3 may include solder bumps, and/or may include metal pillars (e.g., copper pillars), solder caps formed on metal pillars, and/or the like. The bumps B3 are referred to as “ball grid array (BGA) balls” in some examples. The size of the bumps B3 may be different from (e.g., greater than) the size of the bumps B2.

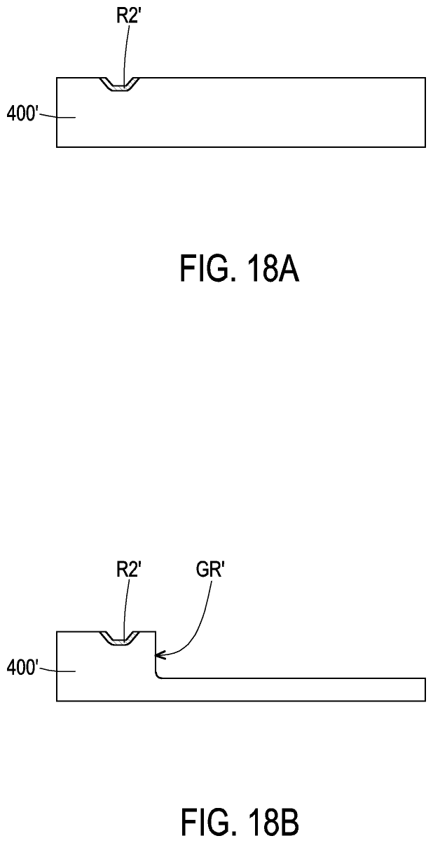

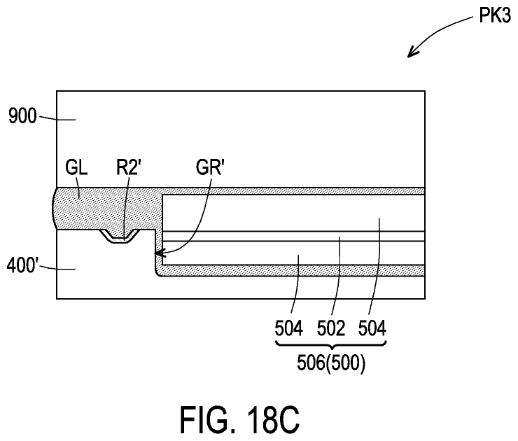

Referring to FIG. 13, an optical package PK3 is provided over the semiconductor package PK1. In some embodiments, the optical package PK3 includes a fiber array unit (FAU) 500 embedded in a substrate 400′ (or called a “carrier” in some examples) and covered by a lid 900 (or called a “cover” in some examples). The method of forming the optical package PK3 is described in varying views in FIG. 18A to FIG. 18C, FIG. 19A and FIG. 19B. FIG. 19A illustrates a simplified top view of some components, and FIG. 19B illustrates a cross-sectional view taken along the line III-III of FIG. 19A.

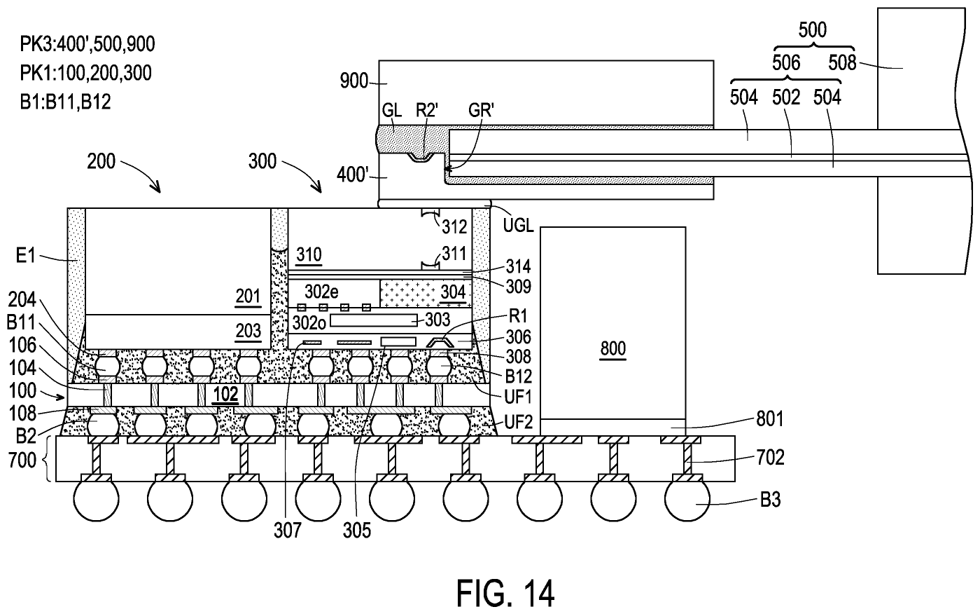

Referring to FIG. 18A, a substrate 400′ is provided. The substrate 400′ may be a glass substrate or a transparent substrate. Thereafter, at least one reflector R2′ is formed at the surface of the substrate 400′. The reflector R2′ is configured to reflect and guide a light beam from an optical fiber 506 to the desired optical component (e.g., the underlying optical lens 403, as shown in FIG. 14 to FIG. 17). Specifically, as shown in FIG. 19A and FIG. 19B, multiple reflectors R2′ correspond to multiple grooves GR′ and the overlying optical fibers 506, respectively. The method of forming the reflectors R2′ includes performing a glass cutting process to form multiple recesses at the surface of the substrate 400′, performing an electroplating process or a sputtering process to form metal (such as copper) on the surfaces of the recesses, and then removing the excess metal outside of the recesses. The glass cutting process may include a diamond blade cutting process or the like. In some embodiments, the substrate 400′ is patterned by a suitable blade to define the desired shape of the recesses, and those recesses and reflectors R2′ have rounded top corners and rounded bottom corners.

Thereafter, one or more grooves GR′ are formed in the substrate 400′. The method of forming the grooves GR′ includes performing a glass cutting process. The glass cutting process may include a diamond blade cutting process or the like. In some embodiments, the substrate 400′ is patterned by a suitable blade to define the desired shape. Specifically, the grooves GR′ have rounded V-shape bottoms. In some embodiments, the substrate 400′ is patterned by a suitable blade to define the desired shape of the grooves GR′, and those grooves GR′ have rounded top corners and rounded bottom corners. In some embodiments, the included angle θ between the top surface and the sidewall of each groove GR′ is about 50 to 70 degrees, such as about 55 to 65 degrees.

Referring to FIG. 18C, a lid 900 is provided over the substrate 400′, so the optical fibers 506 of the FAU 500 are interposed between the substrate 400′ and the lid 900. The lid 900 is configured to protect and fix the underlying substrate 400′ and the FAU 500. The lid 900 may be a glass lid or a transparent lid. Thereafter, an optical glue GL is dispensed into the space between the FAU 500 and each of the substrate 400′ and the lid 900 followed by a curing process. The optical glue GL includes a curable adhesive material and has high light transmittance and high adhesion. The optical glue GL may have a convex surface and extend out from the sidewall of the lid 900. The optical package PK3 including a fiber array unit (FAU) 500 interposed between a substrate 400′ and a lid 900 is thus completed.

Referring to FIG. 14, the optical package PK3 is placed on the semiconductor package PK1. In some embodiments, the reflector R2′ of the optical package PK3 corresponds to the optical lens 312 of the underlying semiconductor package PK1.

Thereafter, a UV-curable optical glue UGL is dispensed into the space between the optical package PK3 and the semiconductor package PK1. The UV-curable optical glue UGL includes a UV-curable adhesive material and has high light transmittance and high adhesion. The UV-curable optical glue UGL may have a convex surface, may extend out from the sidewall of the substrate 400′ of the optical package PK3, and may extend out from the sidewall of the encapsulation layer E1 of the semiconductor package PK1. The “uncured” UV-curable optical glue UGL at this stage is softer and less adhesive, so the overlying optical package PK3 is movable and rotational in the horizontal direction (e.g., along X direction and/or Y direction) and in vertical direction (e.g., X direction). In some embodiments, the location of the optical package PK3 can be adjusted to an appropriate location before the UV-curable optical glue UGL is subjected to a UV curing process, so as to ensure that the optical package PK3 is in place and aligned with the semiconductor package PK1.

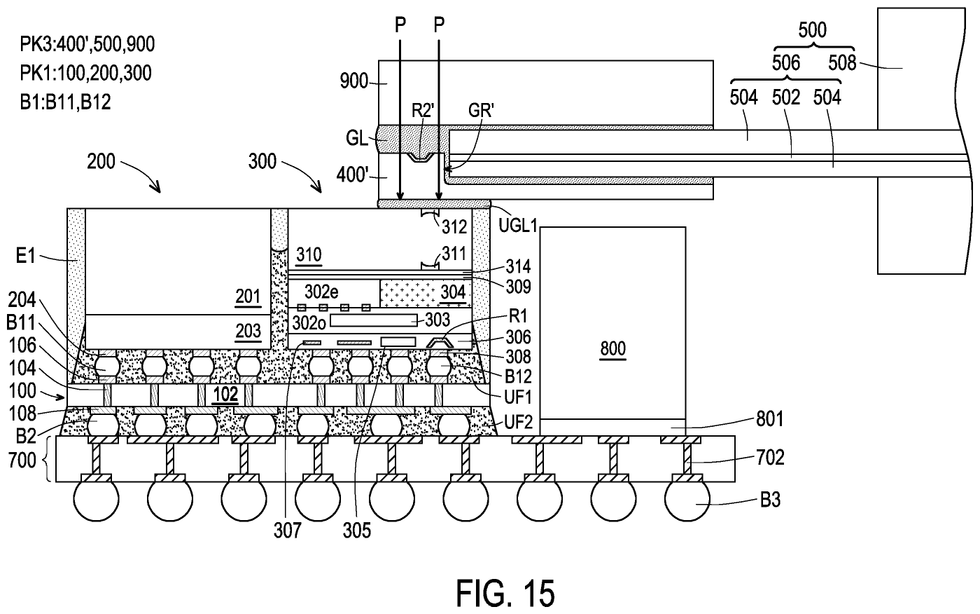

Referring to FIG. 15, a UV curing process P is performed, so a UV light passes through the glass substrate 400′ of the optical package PK3 and reaches the UV-curable optical glue, and the uncured UV-curable optical glue is cured and hardened to form a cured optical glue UGL1. Specifically, after the optical package PK3 is adjusted to the appropriate location, the UV-curable optical glue UGL is cured to fix the location of the optical package PK3.

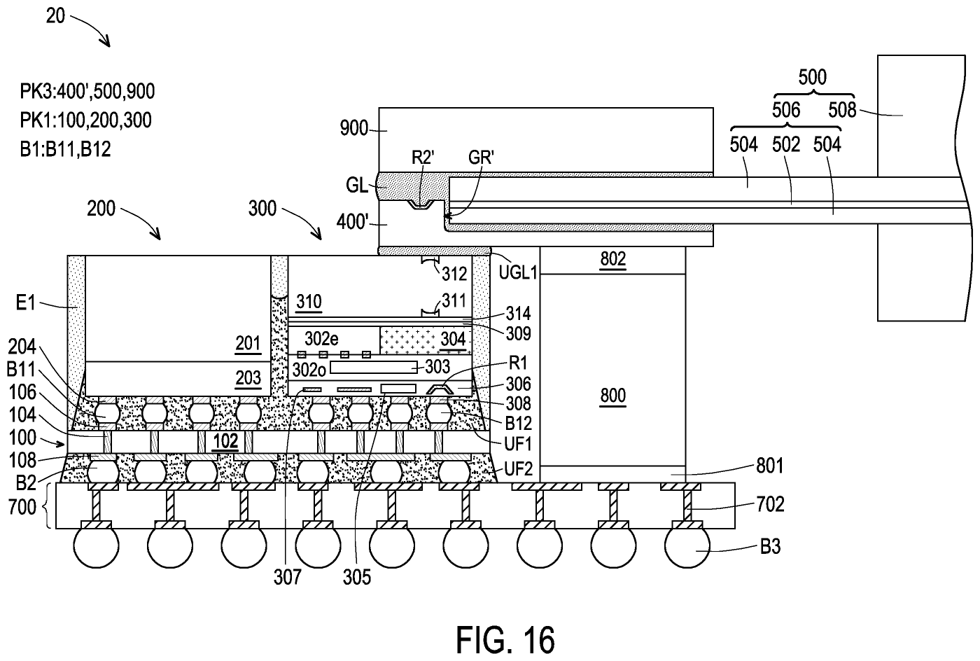

Referring to FIG. 16, after the UV curing process P, a buffer layer 802 is provided between the optical package PK3 and the support structure 800, so as to better support the optical package PK3 and therefore stabilize the entire package assembly. The buffer layer 802 may be an adhesive layer or a thermal interface material (TIM). The back surface of the substrate 400′ is in physical contact with the buffer layer 802 over the support structure 800. The buffer layer 802 is regarded as part of support structure 800 in some examples. A package assembly 20 of the disclosure is thus completed.

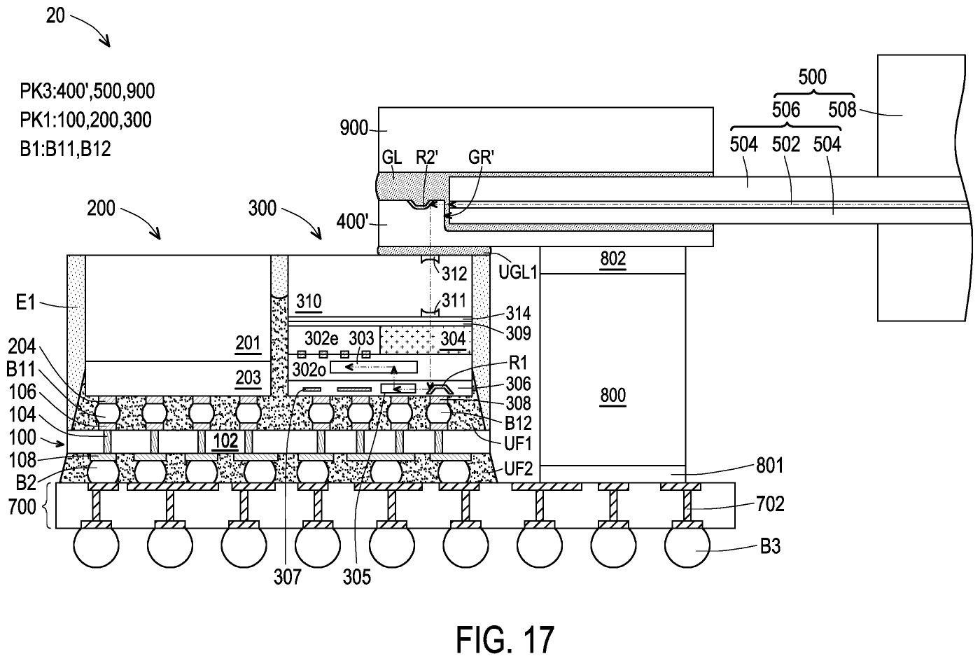

In some embodiments, as shown in FIG. 17, a light beam L propagates through an optical fiber 506, is redirected by the reflector R2′ and then optically coupled to a PIC 303 sequentially through an optical lens 312, an optical lens 311, a reflector R1, and an edge coupler and a silicon nitride waveguide of an optical component 305.

In the disclosure, the substrate with V-grooves for holding a fiber array unit (FAU) is a transparent substrate. Therefore, after an ultra-violet (UV) curable optical glue is dispensed into the space between the substrate and the underlying photonic structure, a UV light can pass through the transparent substrate during the optical glue curing process, so as to increase the adhesion between the substrate and the underlying photonic structure and therefore improve the FAU integration.

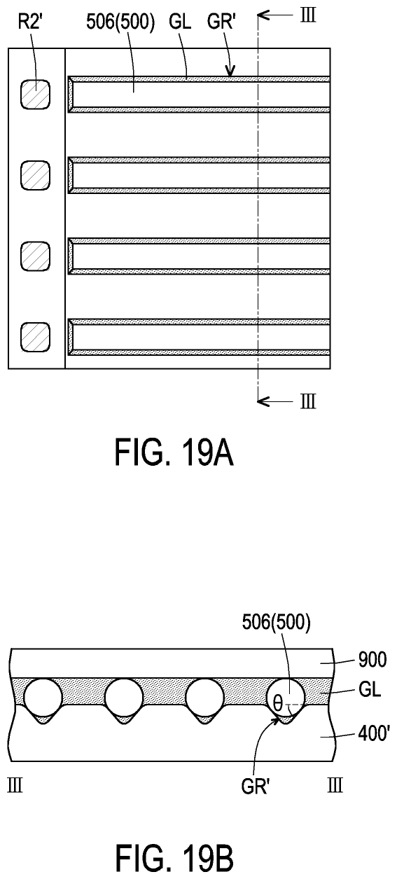

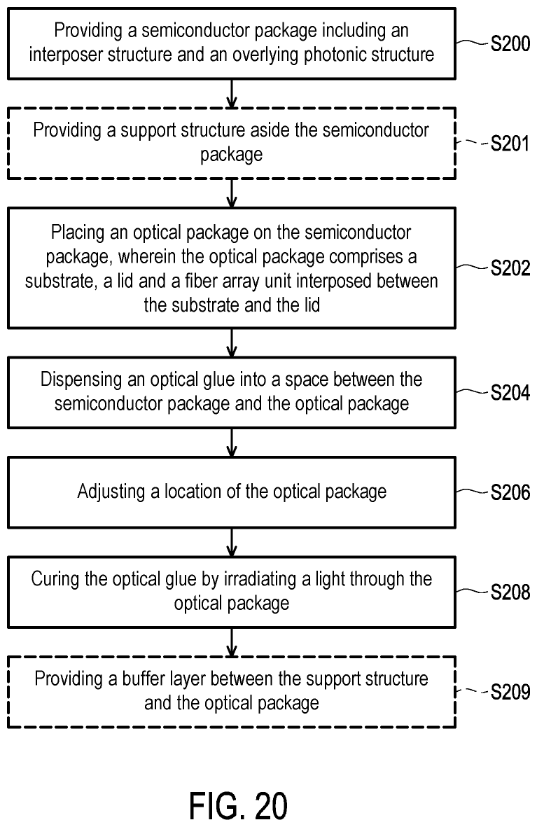

FIG. 20 illustrates a method of forming a package assembly in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act S200, a semiconductor package including an interposer structure and an overlying photonic structure is provided. FIG. 1 and FIG. 12 illustrate cross-sectional views corresponding to some embodiments of act S200.

At act S201, a support structure is provided aside the semiconductor package. FIG. 2 and FIG. 13 illustrate cross-sectional views corresponding to some embodiments of act S201. Act S201 is optional and may be omitted in some examples.

At act S202, an optical package is placed on the semiconductor package, wherein the optical package includes a substrate, a lid and a fiber array unit interposed between the substrate and the lid. FIG. 2, FIG. 7A to FIG. 7J, FIG. 8, FIG. 9, FIG. 10A, FIG. 10B, FIG. 11A and FIG. 11B, FIG. 13, FIG. 18A to FIG. 18C, FIG. 19A and FIG. 19B illustrate varying views corresponding to some embodiments of act S202.

In some embodiments, the substrate includes a semiconductor substrate and at least one transparent region penetrating through the semiconductor substrate. In some embodiments, the substrate includes two transparent regions and an optical lens formed therein, and the optical lens is formed between the two transparent regions. In some embodiments, at least one groove is formed in the substrate, and the fiber array unit is adhered to the at least one groove. In some embodiments, a method of forming the at least one groove includes performing an etching process. See FIG. 2, FIG. 7A to FIG. 7J, FIG. 8, FIG. 9, FIG. 10A, FIG. 10B, FIG. 11A and FIG. 11B.

In some embodiments, the substrate includes a glass substrate. In some embodiments, at least one groove is formed in the substrate, and the fiber array unit is adhered to the at least one groove. In some embodiments, a method of forming the at least one groove includes performing a glass cutting process. See FIG. 13, FIG. 18A to FIG. 18C, FIG. 19A and FIG. 19B.

At act S204, an optical glue is dispensed into a space between the semiconductor package and the optical package. FIG. 3 and FIG. 14 illustrate cross-sectional views corresponding to some embodiments of act S204. In some embodiments, the optical glue includes a UV-curable optical glue.

At act S206, a location of the optical package is adjusted after dispensing the optical glue. FIG. 3 and FIG. 14 illustrate cross-sectional views corresponding to some embodiments of act S206. Act S206 is performed after act 204 for better optically coupling the optical package and the underlying semiconductor package.

At act S208, the optical glue is cured by irradiating a light through the optical package. FIG. 4 and FIG. 15 illustrate cross-sectional views corresponding to some embodiments of act S208. Act S208 is performed after act S206 for better fixing the optical package and the underlying semiconductor package in place.

At act S209, a buffer layer is provided between the support structure and the optical package. FIG. 5 and FIG. 16 illustrate cross-sectional views corresponding to some embodiments of act S209. Act S209 is optional and may be omitted in some examples. For example, act S201 and act S209 may be omitted as needed.

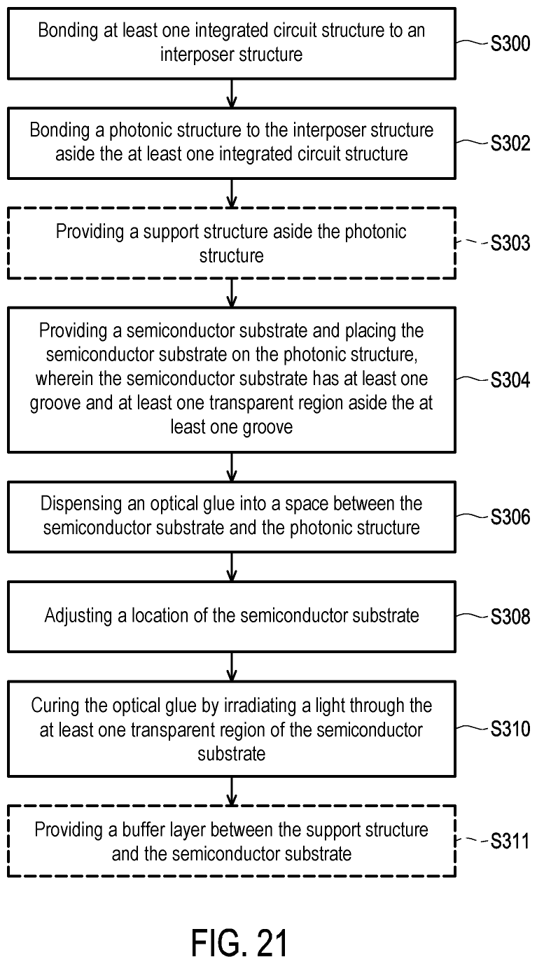

FIG. 21 illustrates a method of forming a package assembly in accordance with some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At act S300, at least one integrated circuit structure is bonded to an interposer structure. FIG. 1 illustrates a cross-sectional view corresponding to some embodiments of act S300.

At act S302, a photonic structure is bonded to the interposer structure aside the at least one integrated circuit structure. FIG. 1 illustrates a cross-sectional view corresponding to some embodiments of act S302.

At act S303, a support structure is provided aside the photonic structure. FIG. 2 illustrates a cross-sectional view corresponding to some embodiments of act S303. Act S303 is optional and may be omitted in some examples.

At act S304, a semiconductor substrate is provided and placed on the photonic structure, wherein the semiconductor substrate has at least one groove and at least one transparent region aside the at least one groove. In some embodiments, the at least one transparent region penetrates through the semiconductor substrate. In some embodiments, an optical lens is formed in the semiconductor substrate aside the at least one transparent region. In some embodiments, at least one optical component and at least one reflector are formed and embedded in at least one dielectric layer over the semiconductor substrate. In some embodiments, a method of forming the at least one groove comprises performing an etching process. FIG. 2, FIG. 7A to FIG. 7J, FIG. 8, FIG. 9, FIG. 10A, FIG. 10B, FIG. 11A and FIG. 11B illustrate varying views corresponding to some embodiments of act S304.

At act S306, an optical glue is dispensed into a space between the semiconductor substrate and the photonic structure. FIG. 3 illustrates a cross-sectional view corresponding to some embodiments of act S306. In some embodiments, the optical glue includes a UV-curable optical glue.

At act S308, a location of the semiconductor substrate is adjusted. FIG. 3 illustrates a cross-sectional view corresponding to some embodiments of act S308. Act S308 is performed after act 306 for better optically coupling the optical package and the underlying semiconductor package.

At act S310, the optical glue is cured by irradiating a light through the at least one transparent region of the semiconductor substrate. FIG. 4 illustrates a cross-sectional view corresponding to some embodiments of act S310. Act S310 is performed after act S308 for better fixing the optical package and the underlying semiconductor package in place.

At act S311, a buffer layer is provided between the support structure and the semiconductor substrate. FIG. 5 illustrates a cross-sectional view corresponding to some embodiments of act S311. Act S311 is optional and may be omitted in some examples. For example, act S303 and act S311 may be omitted as needed.

The package assemblies of the disclosure are illustrated below with reference to FIG. 5 to FIG. 11B and FIG. 16 to FIG. 19B.

In some embodiments, a package assembly 10 includes a semiconductor package PK1, an optical package PK2 and an optical glue UGL1. The semiconductor package PK1 includes an interposer structure 100 and an overlying photonic structure 300. The optical package PK2 is disposed over the semiconductor package PK1. The optical package PK2 includes a substrate 400, a lid 900 and a fiber array unit 500 interposed between the substrate 400 and the lid 900, and the substrate 400 has at least one light-transmitting region 402 therein. The optical glue UGL1 is disposed between and in contact with the photonic structure 300 and the at least one light-transmitting region 402 of the substrate 400.

In some embodiments, the substrate 400 has two light-transmitting regions 402 and an optical lens 403 therein, and the optical lens 403 is disposed between the two light-transmitting regions 402. In some embodiments, the photonic structure 300 of the semiconductor package PK1 has an optical lens 312 corresponding to the optical lens 403 of the substrate 400 of the optical package PK2. In some embodiments, the package assembly 10 further includes a support structure 800 disposed aside the semiconductor package PK1 and configured to support the optical package PK2.

In some embodiments, a package assembly 20 includes a semiconductor package PK1, an optical package PK3 and an optical glue UGL1. The semiconductor package PK1 includes an interposer structure 100 and an overlying photonic structure 300. The optical package PK3 is disposed over the semiconductor package PK1. The optical package PK3 includes a substrate 400′, a lid 900 and a fiber array unit 500 interposed between the substrate 400′ and the lid 900, and the substrate 400′ is a glass substrate. The optical glue UGL1 is disposed between and in contact with the photonic structure 300 and the substrate 400′.

In some embodiments, the substrate 400′ has at least one reflector R2′ at the surface thereof, and the reflector R2′ is laterally aligned with the fiber array unit 500. In some embodiments, the photonic structure 300 of the semiconductor package PK1 has an optical lens 312 corresponding to the reflector R′ of the substrate 400′ of the optical package PK3. In some embodiments, the package assembly 20 further includes a support structure 800 disposed aside the semiconductor package PK1 and configured to support the optical package PK3.

In view of above, in the disclosure, the substrate with V-grooves for holding a fiber array unit (FAU) is transparent in at least a portion thereof. Therefore, after an ultra-violet (UV) curable optical glue is dispensed into the space between the substrate and the underlying photonic structure, a UV light can pass through the transparent portion of the substrate during the optical glue curing process, so as to increase the adhesion between the substrate and the underlying photonic structure and therefore improve the FAU integration.

Many variations of the above examples are contemplated by the disclosure. It is understood that different embodiments may have different advantages, and that no particular advantage is necessarily required of all embodiments.

In accordance with some embodiments of the disclosure, a package assembly includes the following operations. A semiconductor package including an interposer structure and an overlying photonic structure is provided. An optical package is placed on the semiconductor package, wherein the optical package includes s a substrate, a lid and a fiber array unit interposed between the substrate and the lid. An optical glue is dispensed into a space between the semiconductor package and the optical package. A location of the optical package is adjusted after dispensing the optical glue. The optical glue is cured by irradiating a light through the optical package.

In accordance with alternative embodiments of the disclosure, a method of forming a package assembly includes following operations. At least one integrated circuit structure is boned to an interposer structure. A photonic structure is bonded to the interposer structure aside the at least one integrated circuit structure. A semiconductor substrate is provided and placed on the photonic structure, wherein the semiconductor substrate has at least one groove and at least one transparent region aside the at least one groove. An optical glue is dispensed into a space between the semiconductor substrate and the photonic structure. The optical glue is cured by irradiating a light through the at least one transparent region of the semiconductor substrate.

In accordance with yet alternative embodiments of the disclosure, a package assembly includes a semiconductor package, an optical package and an optical glue. The semiconductor package includes an interposer structure and an overlying photonic structure. The optical package is disposed over the semiconductor package, wherein the optical package includes a substrate, a lid and a fiber array unit interposed between the substrate and the lid, and the substrate has at least one light-transmitting region therein. The optical glue is disposed between and in contact with the photonic structure and the at least one light-transmitting region of the substrate.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A method of forming a package assembly, comprising:
providing a semiconductor package comprising an interposer structure and an overlying photonic structure;
placing an optical package on the semiconductor package, wherein the optical package comprises a substrate, a lid and a fiber array unit interposed between the substrate and the lid;
dispensing an optical glue into a space between the semiconductor package and the optical package;
adjusting a location of the optical package after dispensing the optical glue; and
curing the optical glue by irradiating a light through the optical package.

2. The method of claim 1, wherein the optical glue comprises a UV-curable optical glue.

3. The method of claim 1, further comprising:
providing a support structure aside the semiconductor package before placing the optical package; and
providing a buffer layer between the support structure and the optical package after curing the optical glue.

4. The method of claim 1, wherein the substrate comprises a semiconductor substrate and at least one transparent region penetrating through the semiconductor substrate.

5. The method of claim 4, further comprising forming at least one optical component and at least one reflector embedded in at least one dielectric layer over the semiconductor substrate.

6. The method of claim 1, wherein the substrate comprises a glass substrate.

7. The method of claim 1, further comprising forming at least one groove in the substrate, wherein the fiber array unit is adhered to the at least one groove.

8. The method of claim 7, wherein a method of forming the at least one groove comprises performing an etching process.

9. The method of claim 7, wherein a method of forming the at least one groove comprises performing a glass cutting process.

10. A method of forming a package assembly, comprising:
bonding at least one integrated circuit structure to an interposer structure;
bonding a photonic structure to the interposer structure aside the at least one integrated circuit structure;
providing a semiconductor substrate and placing the semiconductor substrate on the photonic structure, wherein the semiconductor substrate has at least one groove and at least one transparent region aside the at least one groove;
dispensing an optical glue into a space between the semiconductor substrate and the photonic structure; and
curing the optical glue by irradiating a light through the at least one transparent region of the semiconductor substrate.

11. The method of claim 10, wherein the optical glue comprises a UV-curable optical glue.

12. The method of claim 10, further comprising adjusting a location of the semiconductor substrate after dispensing the optical glue and before curing the optical glue.

13. The method of claim 10, wherein the at least one transparent region penetrates through the semiconductor substrate.

14. The method of claim 10, further comprising forming an optical lens in the semiconductor substrate aside the at least one transparent region.

15. The method of claim 10, further comprising forming at least one optical component and at least one reflector embedded in at least one dielectric layer over the semiconductor substrate.

16. The method of claim 10, wherein a method of forming the at least one groove comprises performing an etching process.

17. A package assembly, comprising:
a semiconductor package comprising an interposer structure and an overlying photonic structure;
an optical package disposed over the semiconductor package, wherein the optical package comprises a substrate, a lid and a fiber array unit interposed between the substrate and the lid, and the substrate has at least one light-transmitting region therein; and
an optical glue disposed between and in contact with the photonic structure and the at least one light-transmitting region of the substrate.

18. The package assembly of claim 17, wherein the substrate has two light-transmitting regions and a first optical lens therein, and the first optical lens is disposed between the two light-transmitting regions.

19. The package assembly of claim 18, wherein the photonic structure of the semiconductor package has a second optical lens corresponding to the first optical lens of the substrate of the optical package.

20. The package assembly of claim 17, further comprising a support structure disposed aside the semiconductor package and configured to support the optical package.
